(19) United States
(12) Patent Application Publication
(10) Pub. No.: US 2025/0183087 A1
(43) Pub. Date: Jun. 5, 2025

(54) CARRIER LAYER FOR A SEMICONDUCTOR WAFER AND METHOD FOR APPLYING SUCH A CARRIER LAYER TO A SEMICONDUCTOR WAFER

(71) Applicant: Robert Bosch GmbH, Stuttgart (DE)

(72) Inventors: Benjamin Zillmann, Stuttgart (DE); Bernhard Polzinger, Stuttgart (DE); Kristina Vogt, Muenchingen (DE)

(21) Appl. No.: 18/953,554

(22) Filed: Nov. 20, 2024

(30) Foreign Application Priority Data
Dec. 1, 2023 (DE) 10 2023 212 058.5

(51) Int. Cl. H01L 21/683; B41M 5/00

(52) U.S. Cl. CPC H01L 21/6835; B41M 5/0047

(57) ABSTRACT

A carrier layer for a semiconductor wafer with a matrix structure and an ellipsoid structure embedded in the matrix structure. A method for applying such a carrier layer to a semiconductor wafer.

### FIELD

The present invention relates to a carrier layer for a semiconductor wafer and to a method for applying such a carrier layer to a semiconductor wafer.

### BACKGROUND INFORMATION

Semiconductor wafers are available in various designs in the related art.

The production and processing of the conventional semiconductor wafers regularly includes up to 600 individual process steps. Some of the individual process steps, such as final thin grinding of the semiconductor wafer or etching, can cause intrinsic compressive and tensile stresses in the semiconductor wafer. The conventional semiconductor wafers therefore often exhibit a high degree of mechanical bending. This uncontrollable and inhomogeneous bending complicates further processing and increases the risk of breakage. In some cases, further processing of the semiconductor wafer is completely impossible due to the bending.

In order to prevent this, it is also conventional to apply a carrier layer to the semiconductor wafers. The carrier layer is used as a mechanical carrier during further processing steps, including during thin grinding of the semiconductor wafer, in particular during thinning of a substrate layer of the semiconductor wafer. The carrier layer gives the semiconductor wafer stability and thus reduces the risk of damage to the semiconductor wafer.

However, in the case of the conventional carrier layers, heat treatment can cause the carrier layer to distort. This in turn has a negative effect on the properties of the semiconductor wafer.

An object of the present invention is to overcome the disadvantages outlined above.

### SUMMARY

The object may be achieved according to the present invention by the carrier layer having certain features of the present invention and the method for applying such a carrier layer to a semiconductor wafer having certain features of the present invention.

According to the present invention, a carrier layer is provided which comprises a matrix structure and an ellipsoid structure embedded in the matrix structure.

The central idea of the present invention is to design the carrier layer in such a way that it comprises two different structures, namely the matrix structure and the ellipsoid structure. This makes it possible to specifically adapt properties of the carrier layer in different regions to defined requirements and thus to specifically control material distortion of the carrier layer during heat treatment.

In an exemplary embodiment of the carrier layer according to the present invention, it is formed from the matrix structure and the ellipsoid structure embedded in the matrix structure.

The carrier layer can be applied, for example, to a front face of a semiconductor wafer.

The front face of the semiconductor wafer can be a structured semiconductor wafer face having contact regions.

The carrier layer is made of a water-insoluble material, for example.

The carrier layer can be made of a high-vacuum suitable and/or temperature-stable material, i.e., a material of which the material properties do not change even when treated under high vacuum or at different temperatures.

In an exemplary embodiment of the present invention, the carrier layer according to the present invention is inkjet-printed. In particular, the carrier layer can be printed onto the semiconductor wafer by means of inkjet printing.

In a preferred example embodiment of the carrier layer according to the present invention, the matrix structure is formed from a first material and the ellipsoid structure is formed from a second material. The first material has material properties that differ from material properties of the second material.

For example, the ellipsoid structure has a higher stiffness than the matrix structure.

The ellipsoid structure can have a greater thermal expansion than the matrix structure.

In an exemplary embodiment of the carrier layer according to the present invention, the matrix structure is formed from organic or inorganic ink, in particular polymer-based ink.

The ink may contain organic and/or inorganic, in particular mineral or ceramic, fillers. The carrier layer therefore has good thermal and mechanical properties.

In a preferred example embodiment of the carrier layer according to the present invention, the ellipsoid structure comprises a plurality of ellipsoids. The ellipsoid structure can further be formed from the plurality of ellipsoids.

For example, an extension of the ellipsoids in the vertical direction, i.e., an extension of the ellipsoids in the thickness direction of the carrier layer, is larger than an extension of the ellipsoids in the transverse direction. Therefore, the longitudinal axis of the ellipsoids extends, for example, in the thickness direction of the carrier layer.

The carrier layer can be removed from a semiconductor wafer in various ways.

The carrier layer can be formed from a plurality of layers.

For example, the individual layers are cured before another layer is applied on top of them, in particular by means of ultraviolet radiation, thermally and/or by sintering.

The carrier layer can, for example, be applied over the full surface of the front face of the semiconductor wafer, i.e., in such a way that it covers the entire front face of the semiconductor wafer.

In the context of the present invention, “over the full surface” also refers to leaving defined regions of the front face free for the targeted formation of at least one opening in the carrier layer.

The carrier layer can have openings which can be arranged above at least one contact region of the semiconductor wafer.

Furthermore, the present invention relates to a method for applying one of the carrier layers described above to a semiconductor wafer. The carrier layer is applied to the semiconductor wafer in such a way that a matrix structure and an ellipsoid structure embedded in the matrix structure are formed.

In an exemplary embodiment of the method according to the present invention, the carrier layer is applied to the semiconductor wafer by means of inkjet printing.

In a preferred example embodiment of the method according to the present invention, the matrix structure is formed from a first material and the ellipsoid structure is formed from a second material of which the material properties differ from the material properties of the first material.

In an exemplary embodiment of the method according to the present invention, the carrier layer is applied to the semiconductor wafer in such a way that the ellipsoid structure comprises a plurality of ellipsoids, in particular is formed from these, an extension of the ellipsoids in the vertical direction, i.e., an extension of the ellipsoids in the thickness direction of the carrier layer, being greater than an extension of the ellipsoids in the transverse direction.

In an exemplary embodiment of the method according to the present invention, a substrate layer of the semiconductor wafer is thinned, in particular after the carrier layer has been applied to the semiconductor wafer.

After the carrier layer has been applied to the front face of the semiconductor wafer, at least one opening can be made in the carrier layer above at least one contact region of the semiconductor wafer, for example by means of a laser.

Further advantages can be found in the following description of exemplary embodiments of the present invention.

### BRIEF DESCRIPTION OF THE DRAWINGS

The present invention is explained below with reference to a preferred embodiment and the figures.

FIG. 1 is a sectional view through a semiconductor wafer with a carrier layer according to an example embodiment of the present invention.

FIG. 2 is a detailed view of the region A in FIG. 1 in a normal state together with a representation of an outer contour of the region A in a thermally expanded state, according to an example embodiment of the present invention.

FIG. 3 is a detailed view of an ellipsoid of the carrier layer from the front, according to an example embodiment of the present invention.

### DETAILED DESCRIPTION OF EXAMPLE EMBODIMENTS

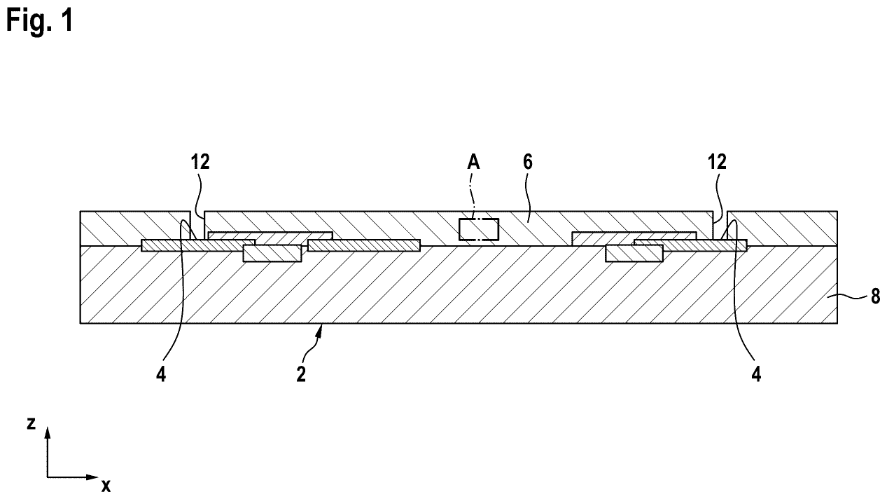

FIG. 1 shows a semiconductor wafer 2 with a carrier layer 6 according to the present invention applied to an upper face of the semiconductor wafer 2.

The semiconductor wafer 2 comprises a substrate layer 8, which is formed in particular from silicon carbide (Sic). Contact regions 4 are arranged on an upper face of the semiconductor wafer 2.

The carrier layer 6 comprises openings 12. The openings 12 are arranged such that the contact regions 4 of the semiconductor wafer 2 are exposed or accessible from above. This allows electrical functional tests to be carried out on the semiconductor wafer 2.

The openings 12 can be introduced into the carrier layer 6 by means of a laser beam after the carrier layer 6 has been applied to the semiconductor wafer 2. Alternatively, the openings 12 can be left out directly when the carrier layer 6 is applied to the semiconductor wafer 2. As a further alternative, in first regions arranged above the contact regions 4, a material can be used which differs from the material of the carrier layer 6 and is water-soluble. Thus, after the carrier layer 6 has been applied to the semiconductor wafer 2, the openings 12 can be exposed in a simple manner by the carrier layer 6 being introduced into a solution.

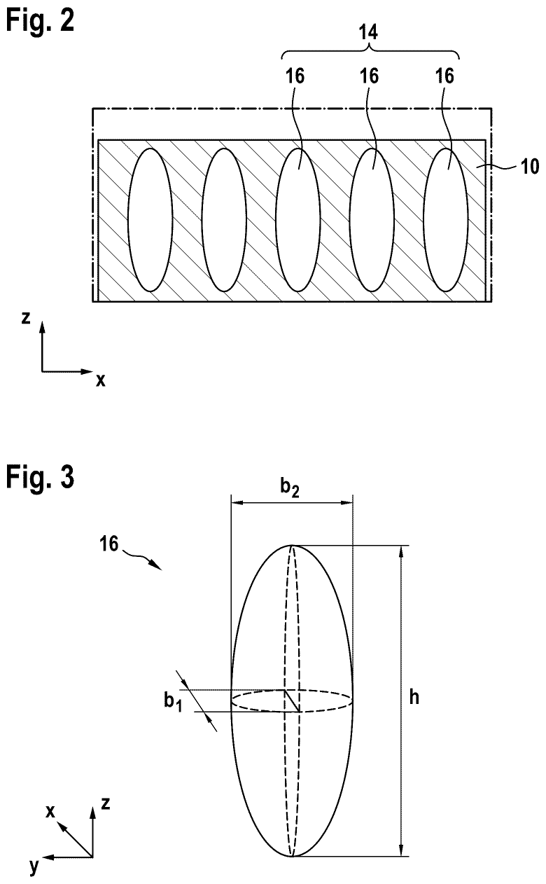

As can be seen in particular from the detailed view of region A in FIG. 2, the carrier layer 6 comprises a matrix structure 10 and an ellipsoid structure 14. The ellipsoid structure 14 has a plurality of ellipsoids 16 which are embedded in the matrix structure 10.

The matrix structure 10 is formed from a first material. The ellipsoid structure 14 consists of a second material which is stiffer and has a greater thermal expansion than the first material.

As can be seen from the isolated representation of an ellipsoid 16 in FIG. 3, the ellipsoids 16 are higher h than wide b₁, b₂. An extension of the ellipsoids 16 in the thickness direction z of the carrier layer 6 is therefore greater than an extension of the ellipsoids 16 in the transverse direction x, y of the carrier layer 6.

The longitudinal extension h of the ellipsoids in the thickness direction z, together with the higher thermal expansion of the second material compared to the first material, causes the carrier layer 6 to expand more in the thickness direction z than in the transverse direction x, y when heated.

While the solid lines in FIG. 2 show the partial region A in a normal state, i.e., in a state in which the carrier layer 6 is 10 not subjected to any heat treatment, the dash-and-dot line in FIG. 2 shows a simplified schematic outline of the partial region A in a heated state of the carrier layer 6.

1-11. (canceled)

12. A carrier layer for a semiconductor wafer, comprising:
a matrix structure; and
an ellipsoid structure embedded in the matrix structure.

13. The carrier layer according to claim 12, wherein the carrier layer is inkjet-printed.

14. The carrier layer according to claim 12, wherein the matrix structure is made of a first material and the ellipsoid structure is made of a second material, the first material having material properties that differ from material properties of the second material.

15. The carrier layer according to claim 12, wherein the ellipsoid structure has a higher stiffness than the matrix structure.

16. The carrier layer according to claim 12, wherein the ellipsoid structure has a greater thermal expansion than the matrix structure.

17. The carrier layer according to claim 12, wherein the matrix structure is made of polymer-based ink, which contains organic and/or inorganic fillers.

18. The carrier layer according to claim 12, wherein the ellipsoid structure includes a plurality of ellipsoids, an extension of the ellipsoids in a vertical direction being greater than an extension of the ellipsoids in a transverse direction.

19. A method for applying a carrier layer according to a semiconductor wafer, the method comprising:
applying the carrier layer to the semiconductor wafer in such a way that a matrix structure and an ellipsoid structure embedded in the matrix structure are formed.

20. The method according to claim 19, wherein the carrier layer is applied to the semiconductor wafer by inkjet printing.

21. The method according to claim 19, wherein the matrix structure is formed from a first material and the ellipsoid structure is formed from a second material of which material properties differ from material properties of the first material.

22. The method according to claim 19, wherein the carrier layer is applied to the semiconductor wafer in such a way that the ellipsoid structure includes a plurality of ellipsoids, an extension of the ellipsoids in a vertical direction being greater than an extension of the ellipsoids in a transverse direction.
